(19) United States
(12) Patent Application Publication
(10) Pub. No.: US 2007/0281395 A1
(43) Pub. Date: Dec. 6, 2007

(54) Method and system for fabricating a semiconductor device

(75) Inventors: Hidehiko Kira, Kawasaki-shi (JP); Masanao Fujii, Kawasaki-shi (JP); Naoki Ishikawa, Kawasaki-shi (JP)

Correspondence Address: Armstrong, Kratz, Quintos, Hanson & Brooks, LLP, Suite 1000, 1725 K Street, N.W., Washington, DC, 20006, US

(73) Assignee: FUJITSU LIMITED, Kawasaki (JP)

(21) Appl. No.: 11/822,978

(22) Filed: Jul. 11, 2007

Related U.S. Application Data
(62) Division of application No. 08/897,953, filed on Jul. 24, 1997.
Application No. 08/897,953 is a continuation of application No. 08/393,677, filed on Feb. 24, 1995, now abandoned.

(30) Foreign Application Priority Data
Apr. 26, 1994 (JP) 6-088762

(51) Int. Cl. H01L 21/58

(52) U.S. Cl. 438/118; 257/E21.505

(57) ABSTRACT

A fabrication method of a semiconductor device is disclosed. The method includes the following steps. First, a given number of projection electrodes are formed on each of a given number of semiconductor chips, and a thermosetting insulating adhesive is applied to areas of mounting parts where the semiconductor chips are to be mounted on a substrate. Second, the thermosetting insulating adhesive on the substrate is heated with a half-thermosetting temperature. Third, the semiconductor chips are aligned to the mounting parts of the substrate and a first fixing of the semiconductor chips is performed with a first pressure. Fourth, the substrate, on which the semiconductor chips are fixed, is heated with a thermosetting temperature of the thermosetting insulating adhesive, and a second fixing of the semiconductor chips is performed with a second pressure.

### BACKGROUND OF THE INVENTION

1. Field of the Invention

The present invention generally relates to a method and a system for fabricating a semiconductor device, and more particularly, to a method and a system for fabricating a semiconductor device, in which a flip-chip connection is performed.

Recently, according to a progress of a high-density integration of the semiconductor device, the flip-chip connection with bumps is frequently used to perform a high-density mounting of a semiconductor chip and to shorten a length of routing lines for requirement of a fast operation. Further, such a semiconductor device has to be fabricated with a low cost. To meet the above requirements, it is necessary to achieve a considerably precise alignment in the mounting of the semiconductor chip with the low cost.

2. Description of the Prior Art

FIGS. 1A to 1E show illustrations for explaining fabrication procedures of a conventional flip-chip-type semiconductor device. In FIG. 1A, a given number of stud-bumps 14 (bonding balls only) are formed on aluminum pads of a semiconductor chip 11 by using a wire 13 (made of, for example, aluminum, copper, gold, etc.) with a wire-bonding technology.

In heights of the stud-bumps 14, there is generally a dispersion of about 20 μm. Therefore, in FIG. 1B, to make the heights of the stud-bumps 14 uniform, the stud-bumps 14 of the semiconductor chip 11 are pressed against a flat glass plate 15 for leveling.

In FIG. 1C, in advance, a conductive adhesive 16 is skidded on a flat glass plate 15a (may be the flat glass plate in FIG. 5B), and a portion 16a of the conductive adhesive 16 on the flat glass plate 15a is adhered to an end of each stud-bump 14 by pressing the stud-bumps 14 against a surface of the conductive adhesive 16 for a given period.

In FIG. 1D, based on a number of the stud-bumps 14 on the semiconductor chip 11, a thermosetting insulating adhesive 18 is applied on a substrate 17, in which mounting pads 17a are formed, for reinforcement by a screen-printing method. And the semiconductor chip 11 which is absorbed by a bonding head (not shown) is moved over the substrate 17.

In FIG. 1E, the stud-bumps 14 on the semiconductor chip 11 are aligned to the mounting pads 17a on the substrate 17. And subsequently, these components are pressed and heated by the bonding head. In this way, the flip-chip connection and the mounting process of the semiconductor chip 11 to the substrate 17 are simultaneously performed.

In this case, the bonding head is equipped with a heat source, and the insulating adhesive 18 is thermoset by the heat source to reinforce the flip-chip connection.

As a method of heating, another method is known in Japanese Laid-Open Patent Application No. 5-67648, wherein the alignment, the heating, and the pressing are simultaneously performed by nozzles arranged around the bonding head to jet hot winds.

Further, another heating method is known in Japanese Laid-Open Patent Application No. 3-184352. In this method, not shown in a drawing here, the bumps of the semiconductor chip are aligned and mounted by only the heating over the mounting pads of the substrate 17. After that, the thermosetting insulating adhesive is applied and infiltrated into the mounting pads and the bumps. Then the insulating adhesive is thermoset by heating it in a heating block or thermostat.

In FIG. 1E, the mounting pads 17a and the stud-bumps 14 are not only aligned and pressed, but are also heated to thermoset the insulating adhesive 18. However, a fabrication apparatus for performing such processes must have a considerably precise alignment mechanism and a heating mechanism. A cost of such a fabrication apparatus is high. Therefore, by spending time for thermosetting the insulating adhesive 18 with the high-cost fabrication apparatus, there is thus a problem that a mounting cost of the semiconductor chip is increased.

On the other hand, in the Japanese Laid-Open Patent Application No. 3-184352, first the semiconductor chip is mounted by pressing only, and next it is heated. However, a difference (about 4 times) in thermal expansion between the semiconductor chip and the substrate makes the flip-chip connection imperfect.

### SUMMARY OF THE INVENTION

It is an object of this invention to provide a method and a system for fabricating a semiconductor device, in which a fabrication apparatus cost and a fabrication cost may be reduced, and a perfect flip-chip connection may be performed, in which the disadvantages described above are eliminated.

The object described above is achieved by a fabrication method of a semiconductor device comprising the steps of: (a) forming a given number of projection electrodes on each of a given number of semiconductor chips, and applying a thermosetting insulating adhesive to areas of mounting parts where the semiconductor chips are to be mounted on a substrate; (b) heating the thermosetting insulating adhesive on the substrate with a half-thermoset temperature; (c) aligning the semiconductor chips to the mounting parts of the substrate and performing a first fixing of the semiconductor chips with a first pressure; and (d) heating the substrate, on which the semiconductor chip is fixed, with a thermosetting temperature of the thermosetting insulating adhesive, and performing a second fixing of the semiconductor chips with a second pressure.

The object described above is also achieved by the fabrication method of the semiconductor device described above, wherein the first pressure is lower than the second pressure.

The object described above is further achieved by the fabrication method of the semiconductor device described above, wherein the second fixing is simultaneously performed for each of semiconductor chips with the second pressure.

In addition, the object described above is achieved by the fabrication method of the semiconductor device described above, wherein the given number of the projection electrodes are formed as studs by wire bonding, the studs being leveled.

The object described above is further achieved by the fabrication method of the semiconductor device described above, wherein the step (a) further comprises the step (a-1) of forming a conductive adhesive on the projection electrodes.

The object described above is also achieved by the fabrication method of the semiconductor device described above, wherein in the step (a-1), the conductive adhesive on the projection electrodes is formed by a conductive adhesive, which has been skidded on a plate, being transcribed onto the projection electrodes.

The object described above is also achieved by a fabrication system of a semiconductor device comprising: a chip loading device forming a given number of projection electrodes on each of a given number of semiconductor chips; a substrate loading device loading a substrate having mounting parts on which the semiconductor chips are to be mounted; an adhesive-application device applying a thermosetting insulating adhesive to areas of the mounting parts of the substrate; an alignment-and-pressing device heating the thermosetting insulating adhesive on the substrate with a half-thermosetting temperature, aligning the semiconductor chips to the mounting parts of the substrate, and performing a first fixing of the semiconductor chips with a first pressure; and a pressing-and-heating device heating the substrate, on which the semiconductor chips are fixed, with a thermosetting temperature of the thermosetting insulating adhesive, and performing a second fixing of the semiconductor chips with a second pressure.

According to the fabrication method of the semiconductor chip, first the semiconductor chip, on which the projection electrodes are formed, is aligned to the substrate, and is fixed in the first fixing by the pressing only. After that, the pressing and heating for thermosetting the insulating adhesive are performed. In such way, the first fixing is performed in a different process from the pressing and heating.

In such a process, a less expensive apparatus may be individually applied for an alignment mechanism and a heating mechanism, so that a cost of fabrication apparatus may be reduced. And since at the final pressing and heating, the alignment is already finished, several processes, such as pressing, heating, and aligning, may be performed by a single process. Thus, throughput is improved, and, as a result, a fabrication cost may be also reduced.

And according to the fabrication method of the semiconductor chip, the first pressure is lower than the second pressure. Therefore, when the semiconductor chip with the projection electrodes is fixed in the first fixing with the first pressure, a dispersion of a degree of collapse of the projection electrodes may be absorbed.

Further according to the fabrication method of the semiconductor chip, the second fixing of the semiconductor chips is performed for each semiconductor chip with the second pressure. Therefore, multi-heads for pressing and heating become available, which leads to an improved mounting operation.

Other objects and further features of the present invention will be apparent from the following detailed description when read in conjunction with the accompanying drawings.

### BRIEF DESCRIPTION OF THE DRAWINGS

FIGS. 1A to 1E show illustrations for explaining fabrication procedures of a conventional flip-chip-type semiconductor device;

FIG. 2 shows an overall block diagram of a fabrication system for realizing a fabrication method according to the present invention;

FIG. 3 shows a flowchart explaining fabrication procedures of a semiconductor device according to the present invention;

FIGS. 4A to 4F show illustrations for explaining the fabrication procedures of the semiconductor device according to the present invention; and

FIG. 5 shows an overall illustration of the semiconductor device as a multi-chip module fabricated according to the present invention.

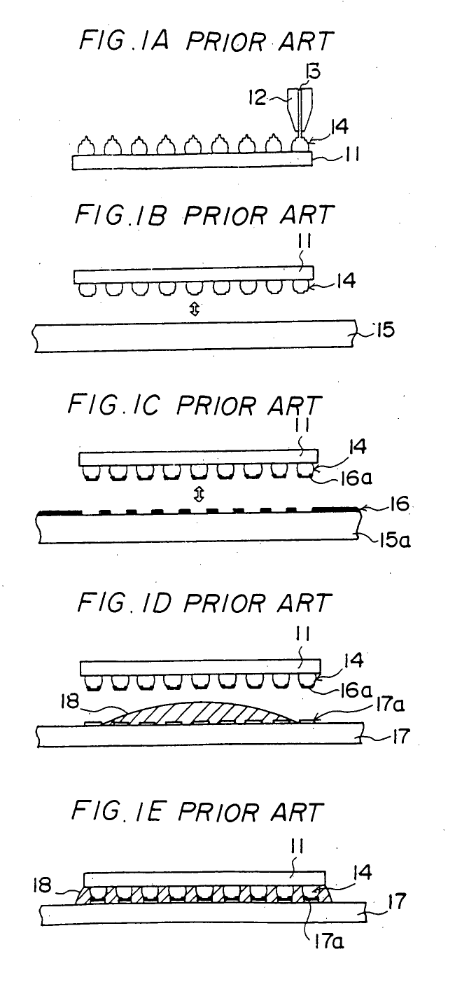

### DESCRIPTION OF THE PREFERRED EMBODIMENTS

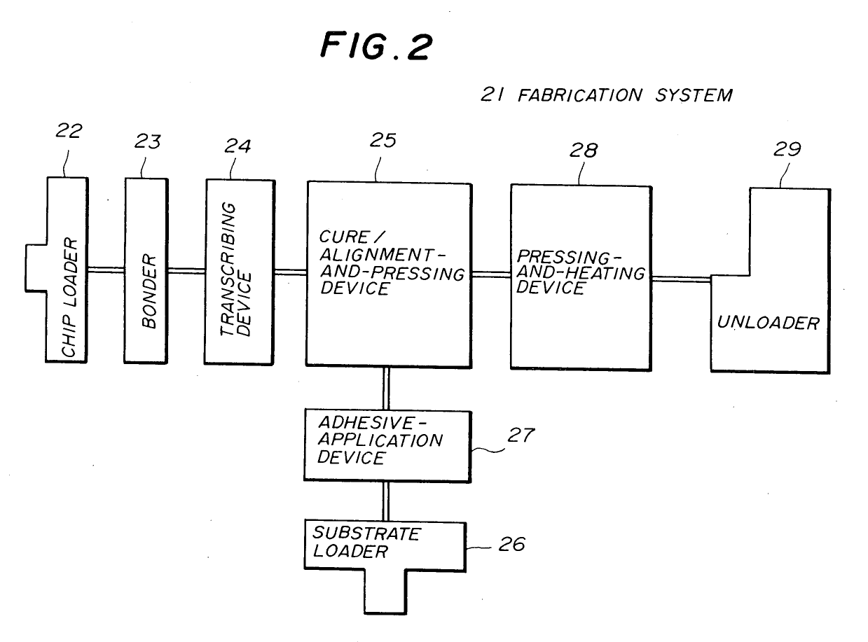

First, a description will be given of first embodiment of a fabrication method of a semiconductor device according to the present invention, by referring to FIG. 2. FIG. 2 shows an overall block diagram of a fabrication system 21 for realizing the fabrication method according to the present invention.

In the fabrication system shown in FIG. 2, a chip loader 22 supplies a semiconductor chip on which a given number of electrode pads (e.g. aluminum pads) are formed, and a bonder 23 forms stud-bumps as projection electrodes on the semiconductor chip by means of a wire-bonding technology.

A transcribing device 24 transcribes a conductive adhesive on a surface of the stud-bumps. A cure/alignment-and-pressing device 25 heats a substrate with an adhesive-half-thermosetting temperature, and aligns the semiconductor chip, on which stud-bumps are formed, to the substrate by a stepper to perform a first fixing with a first pressure.

A substrate loader 26 supplies the substrate on which mounting pads as a mounting part are formed based of a number of the stud-bumps of each semiconductor chip. An adhesive-application device 27 applies, to the supplied substrate, a constant amount of a thermosetting insulating adhesive on areas of the mounting pads which correspond to each semiconductor chip, by using a dispenser, and then supplies the substrate to the cure/alignment-and-pressing device 25.

A pressing-and-heating device 28 presses the semiconductor chip fixed on the substrate with a second pressure, and heats it with a temperature by which the insulating adhesive is thermoset to perform a second fixing. An unloader 29 issues the substrate on which the semiconductor chip is mounted.

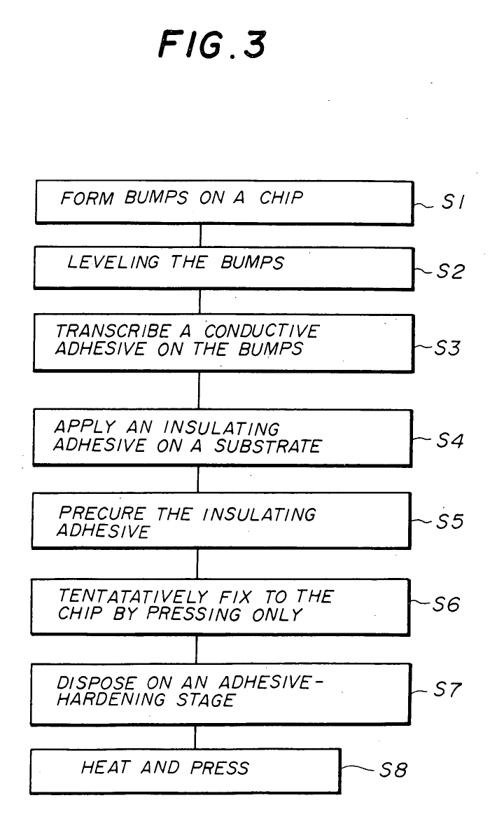

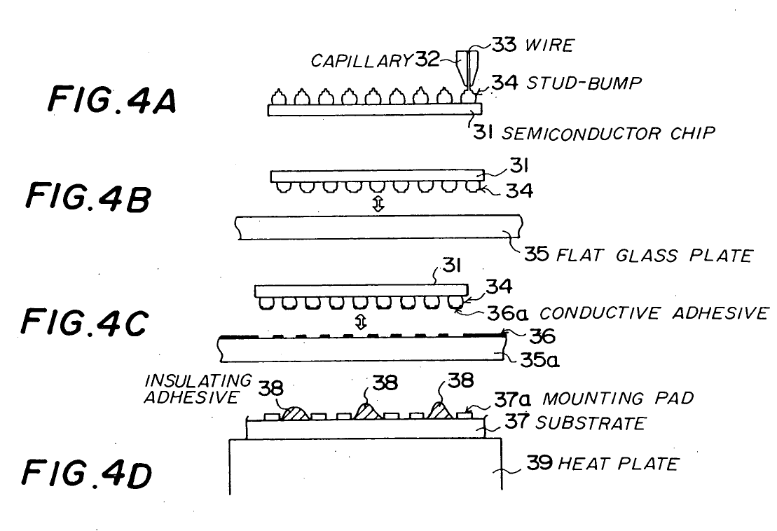

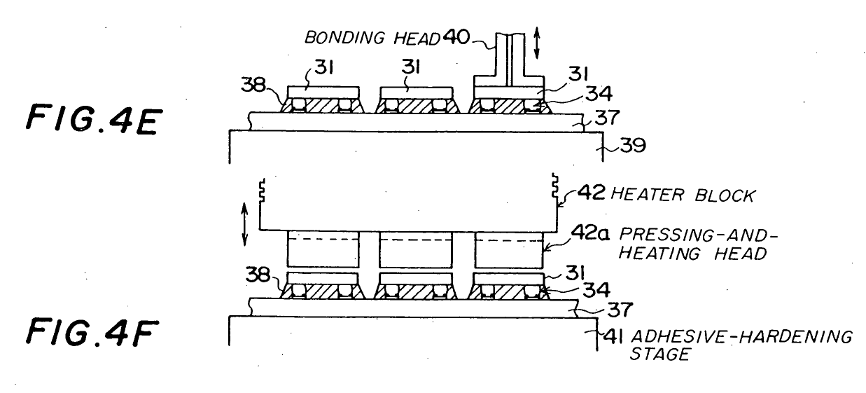

FIG. 3 shows a flowchart explaining fabrication procedures of the semiconductor device according to the present invention, and FIGS. 4A to 4F show illustrations for explaining the fabrication procedures of the semiconductor device according to the present invention. First, a semiconductor chip 31 is moved from the chip loader 22 to the bonder 23, stud-bumps 34 are generated from a wire 33 (for example an aluminum wire, and for electrode pads made of copper or gold, a copper wire or a gold wire) by a capillary 32, and subsequently, by means of a wire-bonding technology, the stud-bumps 34 are formed on electrode pads (not shown) which are formed on the semiconductor chip 31 (a step S1 in FIG. 3, FIG. 4A).

In these stud-bumps 34 on the semiconductor chip 31, there is a dispersion of height of about 20 μm. Therefore, to make their height uniform, the stud-bumps 34 are pressed to a flat glass plate 35 for leveling (a step S2 in FIG. 3, FIG. 4B). Then, the semiconductor chip 31 is moved to the transcribing device 24.

In the transcribing device 24, in advance, a conductive adhesive 36 is skidded thinly on a flat glass plate 35a. A conductive adhesive 36a is transcribed on surfaces of the stud-bumps 34 by pressing the stud-bumps 34 to the conductive adhesive 36 with heating (a step S3 in FIG. 3, FIG. 4C). The skidding of the conductive adhesive 36 on the flat glass plate 35a is performed by pushing out the conductive adhesive 36 onto the flat glass plate 35 with a rubber contacted with the conductive adhesive 36 using a skidder.

On the other hand, in the substrate loader 26, mounting pads 37a are formed on a substrate 37 based on a number of the stud-bumps of the semiconductor chip 31, and this substrate 37 with the mounting pads 37a is supplied to the adhesive-application device 27. In this device 27, a thermosetting insulating adhesive 38 is applied in each area of the mounting pads 37a corresponding to each semiconductor chip 31 (a step S4 in FIG. 3). And subsequently, the substrate 37 is moved over a heat plate of the cure/alignment-and-pressing device 25 (FIG. 4D).

This substrate 37 is precured at a temperature by which the insulating adhesive 38 is half-thermoset on the substrate 37, by the heat plate 39 (a step S5 in FIG. 3). At a later step, when the substrate 37 on which the semiconductor chip 31 is mounted is moved to the pressing-and-heating device 28, a positioning gap may happen due to a moving shock. For preventing an occurrence of such a positioning gap, this precuring process is implemented to obtain strong adhesion with the semiconductor chip 31 by half-thermosetting the insulating adhesive 38 (reducing a degree of viscosity and thixotropy).

Then, in the device 25, the semiconductor chip 31 is absorbed by a bonding head 40, and each stud-bump 34 is aligned over a respective mounting pad 37a of the substrate 37. At the same time, the bonding head 40 with the semiconductor chip 31 is pressed against the mounting pads 37a with the first pressure to perform a tentative fixing (a step S6 in FIG. 3, FIG. 4E). Then, the insulating adhesive 38 on the substrate 37 is cured by the heat plate 39.

The substrate 37, onto which all of the semiconductor chip 31 is tentatively fixed, is moved to the pressing-and-heating device 28 by a transiting rail, etc., to dispose it on an adhesive-hardening stage 41 (a step S7 in FIG. 3). A heater block 42, which is able to move freely in a vertical direction, is positioned over the adhesive-hardening stage 41. And the heater block 42 is equipped with a given number of pressing-and-heating heads 42a, the given number corresponding to a number of semiconductor chips 31 or a given number of semiconductor-chip groups. Each of the pressing-and-heating heads 42a has a function which can keep the heads 42a at the same vertical height.

By heating the heater block 42, heat of a temperature which the insulating adhesive 38 is thermoset is transmitted to the pressing-and-heating heads 42a. When the heater block 42 is moved downward, the pressing-and-heating heads 42 are pressed against each semiconductor chip 31 with the second pressure, and simultaneously thermoset the insulating adhesive 38 to perform the second fixing (a step S8 in FIG. 3, FIG. 4F).

In this case, the second pressure is set larger than the first pressure. This method may absorb a dispersion of a degree of collapse of the bumps 34, and a dispersion of a thickness of the mounting pads 37a of the substrate 37, which occur when the substrate 37 is pressed. This method may also absorb a difference of thermal expansion between the substrate 37 and the semiconductor chip 31 during heating. These procedures achieve an significantly improved flip-chip connection.

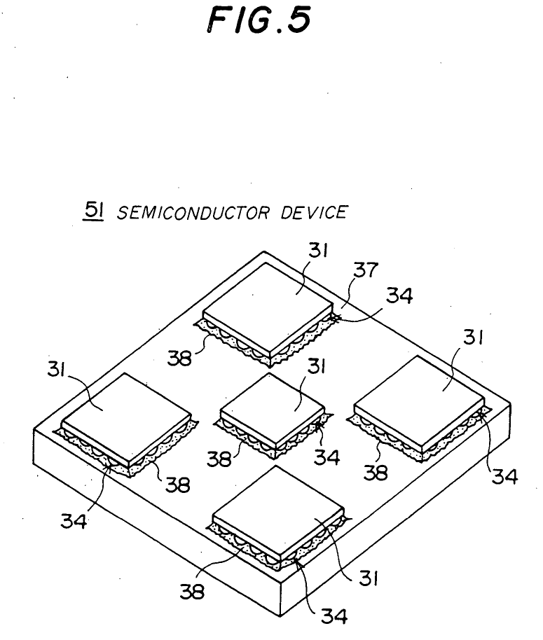

FIG. 5 shows an overall illustration of the semiconductor device as a multi-chip module fabricated according to the present invention. As shown in FIG. 5, the semiconductor device 51 is a multi-chip module in which for example five semiconductor chips 31 are flip-chip-connected with the substrate 37 by the stud-bumps 34, and are fixed to the substrate 37 with the thermosetting insulating adhesive 38.

In this fabrication method of the semiconductor device, a tentative-fixing process for alignment and a pressing-and-heating process are individually performed. Therefore, individual apparatuses for the respective processes may be prepared such as the cure/alignment-and-pressing device 25 for precise alignment and the pressing-and-heating device 28 for pressing and heating. Thus, an expensive apparatus which has both an alignment mechanism and a heating mechanism is unnecessary. The above advantages enable a fabrication apparatus cost to be reduced.

Further, in the cure/alignment-and-pressing device 25, the heating for thermosetting the insulating adhesive 38 is not carried out, but the semiconductor chip 31 is aligned and mounted on the substrate 37. Therefore, it is easy to operate this fabrication apparatus for mounting many chips. This leads to a reduction of a fabrication cost.

And a plurality of the pressing-and-heating heads 42a may be implemented in the pressing-and-heating device 28, so that a mounting operation becomes also easier, and this also leads to a reduction of the fabrication cost.

As described above, the present invention has the following features.

According to the fabrication method of the semiconductor chip, first, the semiconductor chip, on which the projection electrodes are formed, is aligned to the substrate, and is fixed in the first fixing by the pressing only. After that, pressing and heating for thermosetting the insulating adhesive are performed. In such way, the first fixing for the precise alignment is performed in a different process from the pressing and heating.

In such a process, a less expensive apparatus may be individually applied for an alignment mechanism and a heating mechanism, so that the cost of the fabrication apparatus may be reduced. And at the final pressing and heating, the alignment is already finished, therefore, several processes, such as pressing, heating, and aligning, may be performed by a the single process. Thus, the throughput is improved, and as a result, the fabrication cost may be also reduced.

And according to the fabrication method of the semiconductor chip, the first pressure is lower than the second pressure. Therefore, when the semiconductor chip with the projection electrodes is fixed in the second fixing with the second pressure, the dispersion of the degree of collapse of the projection electrodes may be absorbed.

Further according to the fabrication method of the semiconductor chip, the second fixing of the semiconductor chips is performed for each semiconductor chip with the second pressure. Therefore, multi-heads for pressing and heating become available, which leads to the improved mounting operation.

Further, the present invention is not limited to these embodiments, but various variations and modifications may be made without departing from the scope of the present invention.

1-10. (canceled)

11. A method for mounting chips on a substrate, comprising:
coating thermosetting adhesive onto areas of the substrate where the chips are to be mounted;
heating the substrate with a first temperature, to reduce a degree of viscosity and thixotropy of the thermosetting adhesive;
aligning the chips onto the substrate;
pressing the chips to the substrate with a first pressure, without heating the chips;
pressing and heating the chips with a second pressure, which is greater than the first pressure, and with a second temperature which is a thermosetting temperature, to harden the thermosetting adhesive.

12. A method for mounting chips on a substrate, comprising:
coating thermosetting adhesive onto areas of the substrate where the chips are to be mounted;
precuring the thermosetting adhesive by heating the substrate with a first temperature;
pressing the chips to the substrate with a first pressure;
curing the thermosetting adhesive; and
pressing and heating the chips with a second pressure, which is greater than the first pressure, and with a second temperature which is a thermosetting temperature, to harden the thermosetting adhesive.

13. A method for mounting chips on a substrate, comprising:
applying a thermosetting insulating adhesive to areas to mounting parts where the semiconductor chips are to be mounted on a substrate;
heating the thermosetting insulating adhesive on the substrate with a half-thermosetting temperature by heating means to half-thermoset the thermosetting insulating adhesive, so as to reduce a degree of viscosity and thixotropy of the thermosetting insulating adhesive;
aligning the semiconductor chips to the mounting parts of the substrate at a first stage, and performing a first fixing of the semiconductor chips with a first pressure by a bonding head to which the semiconductor chips are absorbed, the semiconductor chips each being pressed separately;
moving the substrate to a second stage, while the semiconductor chips on the mounting parts of the substrate are held at their position by the half-thermosetting state of the thermosetting insulating adhesive; and
heating the substrate on which the semiconductor chips are fixed, at the second stage, with a thermosetting temperature of thermosetting insulating adhesive, and performing a second fixing of the semiconductor chips with a second pressure, wherein the second pressure is greater than the first pressure, the plurality of semiconductor chips being pressed simultaneously in the second stage.
